(19) United States
(12) Patent Application Publication
(10) Pub. No.: US 2026/0327845 A1
(43) Pub. Date: Oct. 22, 2026

(54) Single Crystal Furnace and Crystal Ingot Growth Method

(71) Applicant: XI’AN ESWIN MATERIAL TECHNOLOGY CO., LTD., Xi'an (CN)

(72) Inventor: Wenwu YANG, Xi'an (CN)

(21) Appl. No.: 19/486,017

(22) PCT Filed: Nov. 16, 2023
(86) PCT No.: PCT/CN2023/131953

§ 371 Date: Nov. 19, 2025

(30) Foreign Application Priority Data
May 19, 2023 (CN) 202310572370.1

(51) Int. Cl. C30B 15/10; C30B 15/14; C30B 15/20; C30B 29/06

(52) U.S. Cl. CPC C30B 15/10; C30B 15/14; C30B 15/206; C30B 29/06

(57) ABSTRACT

A single crystal furnace and a crystal ingot growth method are provided. The single crystal furnace includes a furnace body and a crucible assembly located in the furnace body, a reflector is arranged above the crucible assembly, a crystal ingot lifting area is arranged inside the reflector, and a water-cooling jacket is arranged between the crystal ingot lifting area and the reflector; in an axial direction of the water-cooling jacket, a temperature regulator tube is arranged between the water-cooling jacket and the reflector.

### CROSS-REFERENCE TO RELATED APPLICATION

The present application is the U.S. national phase of PCT Application No. PCT/CN2023/131953 filed on Nov. 16, 2023, which claims a priority to the Chinese patent application No. 202310572370.1 filed in China on May 19, 2023, disclosures of which are incorporated herein by reference in their entireties.

### TECHNICAL FIELD

The present application relates to the technical field of silicon product manufacturing, and in particular, to a single crystal furnace and a crystal ingot growth method.

### BACKGROUND

Oxygen is the most important unintentional impurity in Czochralski grown silicon single crystals, which is introduced by the quartz crucible during the crystal growth process. During the cooling process of the crystal, Oxygen atoms will form native oxygen precipitates, which may either dissolve or further grow during subsequent thermal processes in device wafer manufacturing. Oxygen precipitation is the most important micro defect in Czochralski grown silicon single crystals, known as a Bulk Micro Defect (BMD), which has an important impact on the properties of monocrystalline silicon wafers and the yield of device wafers. Oxygen precipitation of suitable size is beneficial to improve the mechanical properties of silicon wafers and thus suppress warping in high-temperature processes. In addition, oxygen precipitation and the associated defects within the bulk of silicon wafers can serve as effective gettering sites, facilitating the absorption of metal contaminations on the surface of silicon wafers, a process known as internal gettering. Controlling and utilizing oxygen precipitation in the device manufacturing process is the core issue of silicon wafer defect engineering. Typically, a defect-free and metal-free clean zone is formed in the near-surface area of the silicon wafer, while a high-density of the BMD formed in the wafer bulk can improve the production yield.

Generally, a higher cooling rate is required during the growth of BMD crystal ingots. The closer the water-cooling jacket is to the reflector, the higher the cooling rate in this area. However, for safety considerations, the water-cooling jacket cannot be placed too close to melt surface or the reflector. Moreover, if the water-cooling jacket is too close to the reflector, it may compromise the thermal shielding effectiveness of the reflector. This can lead to temperature dissipation at the melt surface, causing fluctuations in the solid-liquid-gas triple point, thereby affecting the stable growth of the crystal ingot, and affecting the interactions between vacancy-type defects and interstitial atoms within the crystal ingot. Therefore, it is essential to maintain a specific distance between the water-cooling jacket and the reflector, which will reduce the cooling rate and impact the formation of the BMD.

### SUMMARY

To solve the above technical problems, the present application provides a single crystal furnace and a crystal ingot growth method to solve the problem of low cooling rate in the crystal ingot region corresponding to the position between a water-cooling jacket and a reflector.

To achieve the above object, the technical solutions adopted in the embodiments of the present application include: a single crystal furnace, including a furnace body and a crucible assembly located in the furnace body, wherein a reflector is arranged above the crucible assembly, a crystal ingot lifting area is arranged inside the reflector, and a water-cooling jacket is arranged between the crystal ingot lifting area and the reflector;
in an axial direction of the water-cooling jacket, a temperature regulator tube is arranged between the water-cooling jacket and the reflector.

Optionally, in the axial direction of the water-cooling jacket, the temperature regulator tube has a first end distal from the crucible assembly and a second end proximate to the crucible assembly;
wherein the first end is connected to the water-cooling jacket, and an interspace is arranged between the second end and the reflector; or a interspace is arranged between the first end and the water-cooling jacket, and the second end is connected to the reflector.

Optionally, the interspace is arranged between the first end and the water-cooling jacket, and the second end is connected to the reflector, wherein in a radial direction of the water-cooling jacket, a spacing between the temperature regulator tube and the water-cooling jacket is 2 mm-5 mm.

Optionally, the first end has a first region, and an orthographic projection of the first region onto the water-cooling jacket is located within the water-cooling jacket.

Optionally, the first region comprises a surface proximate to the water-cooling jacket, and a concave-convex structure is arranged on the surface.

Optionally, the concave-convex structure includes a plurality of protrusions and recesses extending in a circumferential direction of the temperature regulator tube, to enable the concave-convex structure to be wave-shaped.

Optionally, in the radial direction of the water-cooling jacket, the temperature regulator tube is disposed between the water-cooling jacket and the reflector.

Optionally, in the axial direction of the water-cooling jacket, a thickness of a side wall of the temperature regulator tube gradually decreases along a direction away from the crucible assembly.

Optionally, the reflector includes a main body and an extension portion, and the extension portion is formed by bending and extending an end of the reflector proximate to the crucible assembly toward the crystal ingot lifting area;
the extension portion has a first surface distal from the crucible assembly, a groove is arranged on the first surface and configured to be connected with the temperature regulator tube, wherein in the radial direction of the water-cooling jacket, the groove has a first side wall distal from the crystal ingot lifting area, and a locking slot is arranged on the first side wall and extends in the radial direction of the water-cooling jacket;
the second end of the temperature regulator tube is provided with a stopper matched with the locking slot.

Optionally, in the radial direction of the water-cooling jacket, the groove has a second side wall proximate to the crystal ingot lifting area; and in the axial direction of the water-cooling jacket, the second side wall extends in a direction away from the crucible assembly to form a blocking wall.

Optionally, the reflector is made of carbon fiber composite material; fiber tows of the carbon fiber composite material in the main body extend in a direction parallel to the axial direction of the reflector; and the fiber tows of the carbon fiber composite material in the extension portion extend in a direction parallel to the radial direction of the reflector.

Optionally, an outer surface of the reflector is arranged with an encapsulation coating.

Optionally, the encapsulation coating on an outer surface of the main body is a tungsten carbide coating, the encapsulation coating on a bottom surface of the extension portion proximate to the crucible assembly is a tungsten carbide coating, and the encapsulation coating on a surface of the extension portion other than the bottom surface is a pyrolytic carbon coating.

Optionally, a heat-absorbing coating is arranged on an inner surface of the water-cooling jacket.

Optionally, in the axial direction of the water-cooling jacket, a thickness of the heat absorption coating gradually decreases along a direction away from the crucible assembly.

The present application also provides a crystal ingot growing method, including:
placing nitrogen-doped polysilicon material in a quartz crucible;
sealing and evacuating a furnace body of the single crystal furnace, and introducing an inert gas into the furnace body;
heating the furnace body to melt the polysilicon material;
lowering multiple seed crystals into corresponding sub-chambers to perform a growth process including dip, shoulder, shoulder-to-body transition and body process.

The beneficial effect of the present application includes, through the arrangement of the temperature regulator tube, the heat in the area corresponding to the temperature regulator tube can be transmitted to the water-cooling jacket, thereby increasing the cooling rate in the area, which can further facilitate the formation of a Bulk Micro Defect (BMD).

### BRIEF DESCRIPTION OF THE DRAWINGS

FIG. 1 is a schematic structural diagram of a single crystal furnace in an embodiment of the present application;

FIG. 2 is a schematic structural diagram of a reflector in an embodiment of the present application;

FIG. 3 is a schematic structural diagram of a temperature regulator tube in an embodiment of the present application.

### DETAILED DESCRIPTION

In order to make the objects, technical solutions, and advantages of the embodiments of the present disclosure clearer, the technical solutions of the embodiments of the present disclosure will be described clearly and comprehensively below in conjunction with the drawings of the embodiments of the present disclosure. Obviously, the described embodiments are part of, but not all of, the embodiments of the present disclosure. Based on the described embodiments of the present disclosure, all other embodiments obtained by those of ordinary skill in the art without making creative efforts fall within the scope of protection of the present disclosure.

Unless otherwise defined, the technical terms or scientific terms used in the present disclosure shall have the ordinary meaning as understood by those skilled in the art to which the present disclosure belongs. The terms “first”, “second” and similar expressions used in the present disclosure do not denote any order, quantity or importance, but are merely used to distinguish between different components. Similarly, expressions such as “a”, “an” or “the” do not imply numerical limitations but indicate the presence of at least one. The terms “comprise”, “include”, or similar expressions mean that the elements or objects appearing preceding the term encompass the elements or objects listed after the term and their equivalents, without excluding other elements or objects. Terms such as “connected” or “coupled” are not limited to physical or mechanical connections, but may include electrical connections, whether direct or indirect. “Up”, “down”, “left”, “right” and the like are only used to indicate relative positional relationships. When the absolute position of the described object changes, the relative positional relationship may also change accordingly.

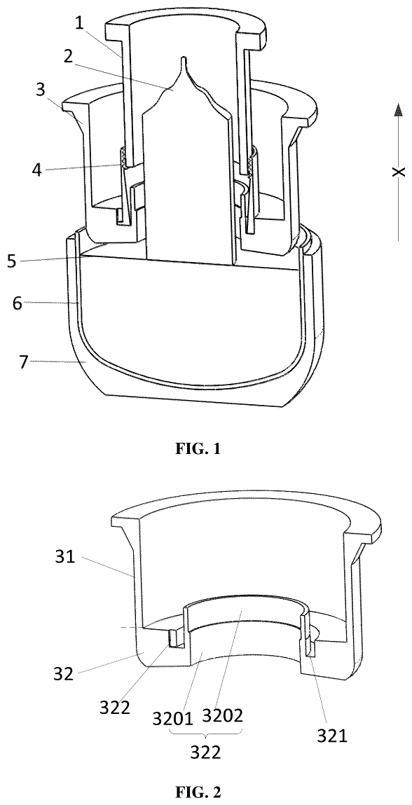

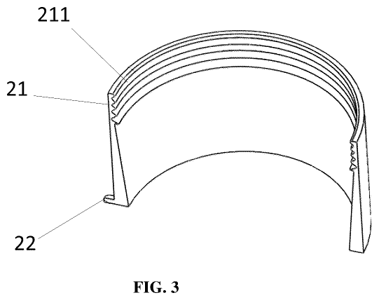

With reference to FIGS. 1 to 3, an embodiment provides a single crystal furnace, which includes a furnace body and a crucible assembly located in the furnace body, wherein the crucible assembly includes a quartz crucible 6 and a graphite crucible 7 arranged in a sleeved configuration, wherein the quartz crucible 6 is used to contain a silicon melt 5, a reflector 3 is arranged above the crucible assembly, a crystal ingot lifting area for growth of a crystal ingot 2 is arranged inside the reflector 3, and a water-cooling jacket 1 is arranged between the crystal ingot lifting area and the reflector 3;

In an axial direction of the water-cooling jacket 1 (refer to an X direction in FIG. 1), a temperature regulator tube 4 is arranged between the water-cooling jacket 1 and the reflector 3.

To achieve the growth of a crystal ingot with high-density BMDs, in the axial direction of the crystal ingot, the area between a water-cooling jacket 1 and the reflector 3 requires a higher cooling rate. However, for safety considerations, the water-cooling jacket 1 cannot be placed too close to the melt surface. Moreover, if the water-cooling jacket 1 is too close to the reflector 3, it may compromise the thermal shielding effectiveness of the reflector 3. This can lead to temperature dissipation at the melt surface, causing fluctuations in the solid-liquid-gas triple point, thereby affecting the stable growth of the crystal ingot, and affecting the reaction between vacancy-type defects and interstitial atoms in the crystal ingot. Therefore, it is essential to maintain a specific distance between the water-cooling jacket 1 and the reflector 3, which results in a lower cooling rate in the area between the water-cooling jacket 1 and the reflector 3 in the axial direction of the crystal ingot. To address this problem, this embodiment provides a single crystal furnace, a temperature regulator tube 4 between the water-cooling jacket 1 and the reflector 3 is arranged, to allow the heat in the area between the water-cooling jacket 1 and the reflector 3, in the axial direction of the crystal ingot, to be transferred to the water-cooling jacket 1, thereby increasing the cooling rate in the area and facilitating the growth of crystal ingots with a high density of the BMDs.

In an exemplary embodiment, in the axial direction of the water-cooling jacket 1, the temperature regulator tube 4 has a first end distal from the crucible assembly and a second end proximate to the crucible assembly;
wherein the first end is connected with the water-cooling jacket 1, and a interspace is arranged between the second end and the reflector 3; or a interspace is arranged between the first end and the water-cooling jacket 1, and the second end is connected with the reflector 3.

It should be noted that, as long as the temperature regulator tube 4 is arranged between the water-cooling jacket 1 and the reflector 3 to increase the cooling rate in the area between the water-cooling jacket 1 and the reflector 3 in the axial direction of the crystal ingot, the connection modes and relative positional relationships among the temperature regulator tube 4, the water-cooling jacket 1 and the reflector 3 can take various forms. For example, the temperature regulator tube 4 may be in contact connection with either the water-cooling jacket 1 or the reflector 3, and in non-contact connection with the other one of the water-cooling jacket 1 and the reflector 3. Alternatively, the temperature regulator tube 4 is in contact connection with both the water-cooling jacket 1 and the reflector 3.

It should be noted that, when the temperature regulator tube 4 is in contact connection with both the water-cooling jacket 1 and the reflector 3, the temperature regulator tube 4 will couple the water-cooling jacket 1 and the reflector 3 together, which is not conducive to the independent motion control of the water-cooling jacket 1 and the reflector 3. Therefore, in some embodiments, optionally, the temperature regulator tube 4 may be in contact connection with either the water-cooling jacket 1 or the reflector 3, while the temperature regulator tube 4 is in non-contact connection with the other one of the water-cooling jacket 1 and the reflector 3.

It should be noted that, when the temperature regulator tube 4 is in non-contact connection with the other of the water-cooling jacket 1 and the reflector 3, in order to ensure heat transfer, the distance between the water-cooling jacket 1 or the reflector 3 (that is in non-contact connection with the temperature regulator tube 4) and the temperature regulator tube 4 is less than a preset value. The setting of the preset value can be determined according to actual needs, as long as the water-cooling jacket 1 or the reflector 3 (that is in non-contact connection with the temperature regulator tube 4) is in a state of being close to but not in contact with the temperature regulator tube 4. In this way, a heat transfer effect between the temperature regulator tube 4 and the water-cooling jacket 1 or the reflector 3 can be achieved; in addition, the contact between the temperature regulator tube 4 and the water-cooling jacket 1 or the reflector 3 is avoided.

It should be noted that, in some embodiments, optionally, the temperature regulator tube 4 is in contact connection with the reflector 3, while the temperature regulator tube 4 is in non-contact connection with the water-cooling jacket 1. This avoids friction between the temperature regulator tube 4 and the reflector 3 during a vertical movement of the water-cooling jacket 1, thereby preventing contamination caused by dust generated by friction. Furthermore, the above-mentioned connection method is conducive to transmitting the heat from the area where the reflector 3 is connected with the temperature regulator tube 4 to the water-cooling jacket 1 through the temperature regulator tube 4.

Referring to FIG. 1, in an exemplary embodiment, the interspace is arranged between the first end and the water-cooling jacket 1, and the second end is connected to the reflector 3, wherein in a radial direction of the water-cooling jacket 1, a spacing between the temperature regulator tube 4 and the water-cooling jacket 1 is 2 mm-5 mm, but not limited to this.

Referring to FIG. 1, in an exemplary embodiment, the first end has a first region 21, and an orthographic projection of the first region 21 onto the water-cooling jacket 1 is located within the water-cooling jacket 1.

In the axial direction of the water-cooling jacket 1, the temperature regulator tube 4 and the water-cooling jacket 1 partially overlap, that is, the orthographic projection of the first region 21 onto the water-cooling jacket 1 is located within the water-cooling jacket 1. This facilitates heat transfer between the temperature regulator tube 4 and the water-cooling jacket 1.

In an exemplary embodiment, the first region 21 comprises a surface proximate to the water-cooling jacket 1, and a concave-convex structure 211 is arranged on the surface of the first region 21.

The arrangement of the concave-convex structure 211 can increase the area of the first region 21 proximate to the water-cooling jacket 1, thereby increasing the heat transfer area between the temperature regulator tube 4 and the water-cooling jacket 1, and thus enhancing the heat transfer effect.

It should be noted that the specific structural forms of the concave-convex structure 211 can be various, as long as the area of the first region 21 proximate to the water-cooling jacket 1 can be increased. Several specific configuration forms of the concave-convex structure 211 in this embodiment are described below.

In an exemplary embodiment, the concave-convex structure 211 includes a plurality of protrusions and recesses extending in a circumferential direction of the temperature regulator tube 4, to allow the concave-convex structure 211 to be wave-shaped.

In an exemplary embodiment, the concave-convex structure 211 includes a plurality of protrusions arranged at intervals on a surface of the first region 21 proximate to the water-cooling jacket 1.

For example, the plurality of protrusions is uniformly distributed in the first region 21.

For example, the plurality of protrusions and the temperature regulator tube 4 are an integrated structure, which simplifies the manufacturing process and enhancing the stability of the connection between the plurality of protrusions and a body of the temperature regulator tube 4.

For example, the plurality of protrusions is formed by extending from corresponding positions on the first region 21 toward a direction approaching the water-cooling jacket 1.

For example, a recess is formed between two adjacent protrusions, that is, the plurality of protrusions is formed by recessing at corresponding positions on the first region 21 in a direction away from the water-cooling jacket 1, so that the protrusions are formed at positions corresponding to the protrusions.

For example, a surface of the first region 21 proximate to the water-cooling jacket 1 includes a first sub-region and a second sub-region that are alternately arranged. The first sub-region extends toward the direction approaching the water-cooling jacket 1 to form the protrusion, thereby forming the concave-convex structure 211 on the surface of the first region 21 proximate to the water-cooling jacket 1; and/or the second sub-region is recessed toward the direction away from the water-cooling jacket 1, so that the concave-convex structure 211 is formed on the surface of the first region 21 proximate to the water-cooling jacket 1.

For example, to prevent the protrusion from damaging the water-cooling jacket 1, an end of the protrusion proximate to the water-cooling jacket 1 is rounded.

For example, to prevent the protrusion from damaging to the water-cooling jacket 1, an end face of the protrusion proximate to the water-cooling jacket 1 is a plane parallel to the axial direction of the water-cooling jacket 1.

For example, to prevent the protrusion from damaging to the water-cooling jacket 1, an end face of the protrusion proximate to the water-cooling jacket 1 is a plane parallel to the axial direction of the water-cooling jacket 1. The protrusion has a side face adjacent to the end face, and a junction between the side face and the end face is rounded to form a curved surface.

In an exemplary embodiment, in a radial direction of the water-cooling jacket 1, the temperature regulator tube 4 is disposed between the water-cooling jacket 1 and the reflector 3.

Specifically, in the radial direction of the water-cooling jacket 1, the first end is located between the reflector 3 and the water-cooling jacket 1, that is, the first end is located between the water-cooling jacket 1 and the reflector 3. The first end is located at a side of the water-cooling jacket 1 distal from the crystal ingot lifting area.

The crystal ingot is located in the crystal ingot lifting area. As is known, the function of the water-cooling jacket 1 is to cool the crystal ingot. The first region 21, where the temperature regulator tube 4 overlaps with the water-cooling jacket 1, is located at the side of the water-cooling jacket 1 distal from the crystal ingot. This arrangement prevents the temperature regulator tube 4 from affecting a cooling effect of the water-cooling jacket 1.

In the axial direction of the water-cooling jacket 1, the length of the first region 21 can be specifically configured according to actual needs. The longer the length of the first region 21 in the axial direction of the water-cooling jacket 1, the larger an overlapping area of the temperature regulator tube 4 and the water-cooling jacket 1. Accordingly, the heat transfer effect between the temperature regulator tube 4 and the water-cooling jacket 1 will be improved. For example, in the axial direction of the water-cooling jacket 1, the length of the first region 21 is 70 mm-100 mm, but the present disclosure is not limited thereto.

It should be noted that, in the axial direction of the water-cooling jacket 1, the setting of the length of the first region 21 is related to the required heat transfer effect, as well as an overall height of the temperature regulator tube 4 and an overall structure of the water-cooling jacket 1 in the axial direction of the water-cooling jacket 1. For example, in a specific embodiment, the length of the first region 21 in the axial direction of the water-cooling jacket 1, is one-quarter of the overall length of the temperature regulator tube 4, but the present disclosure is not limited thereto.

In an exemplary embodiment, in the axial direction of the water-cooling jacket 1, a thickness of a side wall of the temperature regulator tube 4 gradually decreases along a direction away from the crucible assembly.

With the thickness of the side wall of the temperature regulator tube 4 configured as described above, it facilitates the adjustment of the axial temperature gradient of the crystal ingot.

For example, in the radial direction of the reflector 3, the side wall of the temperature regulator tube 4 at the side distal from the crystal ingot lifting area extends parallel to the axial direction of the reflector 3, and in the radial direction of the reflector 3, the side wall of the temperature regulator tube 4 at the side proximate to the crystal ingot lifting area forms an inclined surface relative to the axial direction of the reflector 3.

For example, in the radial direction of the water-cooling jacket 1, the thickness of the side wall of the temperature regulator tube 4 is 9 mm-16 mm, but the present disclosure is not limited thereto.

In an exemplary embodiment, the reflector 3 includes a main body 31 and an extension portion 32 (distinguished by a dotted line in FIG. 2), and the extension portion 32 is formed by bending an end of the reflector 3 proximate to the crucible assembly toward the crystal ingot lifting area and extending the end of the reflector 3 proximate to the crucible assembly toward the crystal ingot lifting area;
the extension portion 32 has a first surface distal from the crucible assembly, a groove 321 is arranged on the first surface and configured to be connected with the temperature regulator tube 4, wherein in the radial direction of the water-cooling jacket 1, the groove 321 has a first side wall distal from the crystal ingot lifting area, and a locking slot 322 is arranged on the first side wall and extends in the radial direction of the water-cooling jacket 1;
the second end of the temperature regulator tube 4 is provided with a stopper 22 matched with the locking slot 322.

The temperature regulator tube 4 may be bonded to the bottom of the groove 321 by an adhesive layer, but the present disclosure is not limited thereto. For example, the temperature regulator tube 4 and the groove 321 may also be connected by an interference fit.

The arrangement of the locking slot 322 and the stopper 22 prevents relative rotation between the temperature regulator tube 4 and the reflector 3.

Referring to FIGS. 1 to 3, the locking slot 322 extends from the first surface toward the bottom of the groove 321. This allows the temperature regulator tube 4 to be inserted into the groove 321 from top to bottom while the stopper 22 is inserted into the locking slot 322.

In an exemplary embodiment, in the radial direction of the water-cooling jacket 1, the groove 321 has a second side wall proximate to the crystal ingot lifting area. In the axial direction of the water-cooling jacket 1, the second side wall extends in a direction away from the crucible assembly to form a blocking wall 323.

The arrangement of the blocking wall 323 improves the connection stability between the temperature regulator tube 4 and the reflector 3.

For example, an encapsulation layer is coated at a side of the blocking wall 323 proximate to the crystal ingot lifting area.

For example, the encapsulation layer adopts a tungsten carbide coating or a pyrolytic carbon coating.

For example, along the axial direction of the reflector 3, the blocking wall 323 includes a first portion 3201 and a second portion 3202, the first portion 3201 is arranged proximate to the crucible assembly and coated with a tungsten carbide coating, and the second portion 3202 is coated with a pyrolytic carbon coating.

Compared with the tungsten carbide coating, offer a more cost-effective solution. However, when evaluating thermal stability and high-temperature resistance, the tungsten carbide coating demonstrate superior performance in comparison to the pyrolytic carbon coating. Since the first portion 3201 is arranged proximate to the crucible assembly, that is, proximate to the solution contained in the crucible assembly, and the temperature of the first portion 3201 is higher than the temperature of the second portion 3202. Therefore, a tungsten carbide coating on the first portion 3201 and a pyrolytic carbon coating on the second portion 3202 are used, and such coating configuration can reduce costs while achieving better encapsulation protection.

To facilitate coating and simplify the process, the first portion 3201 and the second portion 3202 are in a stepped structure in the axial direction of the reflector 3.

For example, along the radial direction of the reflector 3, the second portion 3202 is recessed in a direction away from the crystal ingot lifting area to form the stepped structure.

In an exemplary embodiment, the reflector 3 is made of carbon fiber composite material; fiber tows of the carbon fiber composite material in the main body 31 extend in a direction parallel to the axial direction of the reflector 3; and the fiber tows of the carbon fiber composite material in the extension portion 32 extend in a direction parallel to the radial direction of the reflector 3 to improve the heat transfer effect.

In an exemplary embodiment, an outer surface of the reflector 3 is provided with an encapsulation coating.

The arrangement of the encapsulation coating serves a purpose of encapsulation protection, preventing dust from falling off the surface of the reflector 3 and thereby causing contamination.

In an exemplary embodiment, the encapsulation coating on an outer surface of the main body 31 is a tungsten carbide coating, the encapsulation coating on a bottom surface of the extension portion 32 proximate to the crucible assembly is a tungsten carbide coating, and the encapsulation coating on a surface of the extension portion 32 other than the bottom surface is a pyrolytic carbon coating.

Compared with the tungsten carbide coating, offer a more cost-effective solution. However, when evaluating thermal stability and high-temperature resistance, the tungsten carbide coating demonstrate superior performance in comparison to the pyrolytic carbon coating. Therefore, the pyrolytic carbon coating is applied to the area of the reflector 3 with a higher temperature, while the tungsten carbide coating is applied to the area of the reflector 3 with a lower temperature.

In an exemplary embodiment, a heat-absorbing coating is arranged on an inner surface of the water-cooling jacket 1 to improve a cooling effect.

In an exemplary embodiment, in the axial direction of the water-cooling jacket 1, the thickness of the heat-absorbing coating gradually decreases along the direction away from the crucible assembly. This facilitates the adjustment of the temperature gradient in the axial direction of the formed crystal ingot.

During the crystal ingot growth process, two critical points are particularly important. First is the state of the solid-liquid-gas triple point. During the body growth stage of the crystal ingot, it is required that the growth state at this point must be especially stable. Meanwhile, the axial temperature difference at this point determines initial vacancy concentration and initial interstitial atom concentration in the crystal ingot, which largely determines an initial defect type of the crystal ingot. The second is the thermal history experienced by the crystal ingot after lifting. The thermal history is closely related to an upper heater structure and temperature field. In particular, for lifting crystal ingots with BMD concentration requirements, nitrogen doping is required for crystal lifting. Nitrogen doping offers two key advantages: first, nitrogen can provide the required nucleus embryo for heterogeneous nucleation of oxygen precipitation, reduce the nucleation energy required for the formation of oxygen precipitation, and promote the BMD generation; second, nitrogen will change the axial defect distribution in the crystal ingot. At a certain concentration, nitrogen can enlarge the axial defect-free area (margin area) of the crystal ingot. According to the V/G theory, this will help to increase an adjustment threshold of a lifting speed. The crystal lifting apparatus provided by the present disclosure can largely change the temperature gradient distribution in the high temperature area of the crystal ingot (the area below the water-cooling jacket 1).

To grow a crystal ingot with a higher concentration of the BMD, the embodiments of the present application further provide a crystal ingot growth method, including:
placing nitrogen-doped polysilicon material in a quartz crucible;
sealing and evacuating a furnace body of the single crystal furnace, and introducing an inert gas into the furnace body;
heating the furnace body to melt the polysilicon material;
lowering multiple seed crystals into corresponding sub-chambers to perform a growth process including dip, shoulder, shoulder-to-body transition and body process.

When nitrogen is doped into polysilicon feedstock, it can provide the required nucleus embryo for heterogeneous nucleation of oxygen precipitation, reduce the nucleation energy required for the formation of oxygen precipitation, promote the BMD generation. Furthermore, nitrogen changes the axial defect distribution in the crystal ingot. At a certain concentration, nitrogen can enlarge the axial defect-free area (margin area) of the crystal ingot. According to the V/G theory, this will help increase the adjustment threshold of the lifting speed.

It is to be understood that the above embodiments are merely exemplary embodiments used to illustrate the principles of the present application, and the present application is not limited thereto. For those of ordinary skill in the art, various modifications and improvements can be made without departing from the spirit and essence of the present application, and these modifications and improvements shall also be regarded as falling within the scope of protection of the present application.

1. A single crystal furnace, comprising a furnace body and a crucible assembly located in the furnace body, wherein a reflector is arranged above the crucible assembly, a crystal ingot lifting area is arranged inside the reflector, and a water-cooling jacket is arranged between the crystal ingot lifting area and the reflector; and
wherein in an axial direction of the water-cooling jacket, a temperature regulator tube is arranged between the water-cooling jacket and the reflector.

2. The single crystal furnace according to claim 1, wherein in the axial direction of the water-cooling jacket, the temperature regulator tube has a first end distal from the crucible assembly and a second end proximate to the crucible assembly; and
wherein the first end is connected to the water-cooling jacket, and a interspace is arranged between the second end and the reflector; or a interspace is arranged between the first end and the water-cooling jacket, and the second end is connected to the reflector.

3. The single crystal furnace according to claim 2, wherein the interspace is arranged between the first end and the water-cooling jacket, and the second end is connected to the reflector, wherein in a radial direction of the water-cooling jacket, a spacing bet ween the temperature regulator tube and the water-cooling jacket is 2 mm-5 mm.

4. The single crystal furnace according to claim 2, wherein the first end has a first region, and an orthographic projection of the first region onto the water-cooling jacket is located within the water-cooling jacket.

5. The single crystal furnace according to claim 4, wherein the first region comprises a surface proximate to the water-cooling jacket, and a concave-convex structure is arranged on the surface.

6. The single crystal furnace according to claim 5, wherein the concave-convex structure comprises a plurality of protrusions and recesses extending in a circumferential direction of the temperature regulator tube, to enable the concave-convex structure to be wave-shaped.

7. The single crystal furnace according to claim 3, wherein in the radial direction of the water-cooling jacket, the temperature regulator tube is disposed between the water-cooling jacket and the reflector.

8. The single crystal furnace according to claim 3, wherein, in the axial direction of the water-cooling jacket, a thickness of a side wall of the temperature regulator tube gradually decreases along a direction away from the crucible assembly.

9. The single crystal furnace according to claim 3, wherein:
the reflector comprises a main body and an extension portion, and the extension portion is formed by bending and extending an end of the reflector proximate to the crucible assembly toward the crystal ingot lifting area;
the extension portion has a first surface distal from the crucible assembly, a groove is arranged on the first surface and configured to be connected with the temperature regulator tube, wherein in the radial direction of the water-cooling jacket, the groove has a first side wall distal from the crystal ingot lifting area, and a locking slot is arranged on the first side wall and extends in the radial direction of the water-cooling jacket; and
the second end of the temperature regulator tube is provided with a stopper matched with the locking slot.

10. The single crystal furnace according to claim 9, wherein in the radial direction of the water-cooling jacket, the groove has a second side wall proximate to the crystal ingot lifting area; and in the axial direction of the water-cooling jacket, the second side wall extends in a direction away from the crucible assembly to form a blocking wall.

11. The single crystal furnace according to claim 9, wherein the reflector is made of carbon fiber composite material; fiber tows of the carbon fiber composite material in the main body extend in a direction parallel to the axial direction of the reflector; and the fiber tows of the carbon fiber composite material in the extension portion extend in a direction parallel to the radial direction of the reflector.

12. The single crystal furnace according to claim 9, wherein an outer surface of the reflector is provided with an encapsulation coating.

13. The single crystal furnace according to claim 12, wherein the encapsulation coating on an outer surface of the main body is a tungsten carbide coating, the encapsulation coating on a bottom surface of the extension portion proximate to the crucible assembly is a tungsten carbide coating, and the encapsulation coating on any surface of the extension portion other than the bottom surface is a pyrolytic carbon coating.

14. The single crystal furnace according to claim 1, wherein a heat-absorbing coating is arranged on an inner surface of the water-cooling jacket.

15. The single crystal furnace according to claim 14, wherein, in the axial direction of the water-cooling jacket, a thickness of the heat-absorbing coating gradually decreases along a direction away from the crucible assembly.

16. A crystal ingot growing method, implemented by using the single crystal furnace according to claim 1, comprising:
placing nitrogen-doped polysilicon material in a quartz crucible;
sealing and evacuating a furnace body of the single crystal furnace, and introducing an inert gas into the furnace body;
heating the furnace body to melt the polysilicon material;
lowering multiple seed crystals into corresponding sub-chambers to perform a growth process comprising dip, shoulder, shoulder-to-body transition and body process.

17. The crystal ingot growing method according to claim 16, wherein in the axial direction of the water-cooling jacket, the temperature regulator tube has a first end distal from the crucible assembly and a second end proximate to the crucible assembly; and
wherein the first end is connected to the water-cooling jacket, and a interspace is arranged between the second end and the reflector; or a interspace is arranged between the first end and the water-cooling jacket, and the second end is connected to the reflector.

18. The crystal ingot growing method according to claim 17, wherein the interspace is arranged between the first end and the water-cooling jacket, and the second end is connected to the reflector, wherein in a radial direction of the water-cooling jacket, a spacing between the temperature regulator tube and the water-cooling jacket is 2 mm-5 mm.

19. The crystal ingot growing method according to claim 18, wherein:
the reflector comprises a main body and an extension portion, and the extension portion is formed by bending and extending an end of the reflector proximate to the crucible assembly toward the crystal ingot lifting area;
the extension portion has a first surface distal from the crucible assembly, a groove is arranged on the first surface and configured to be connected with the temperature regulator tube, wherein in the radial direction of the water-cooling jacket, the groove has a first side wall distal from the crystal ingot lifting area, and a locking slot is arranged on the first side wall and extends in the radial direction of the water-cooling jacket; and
the second end of the temperature regulator tube is provided with a stopper matched with the locking slot.

20. The crystal ingot growing method according to claim 19, wherein in the radial direction of the water-cooling jacket, the groove has a second side wall proximate to the crystal ingot lifting area; and in the axial direction of the water-cooling jacket, the second side wall extends in a direction away from the crucible assembly to form a blocking wall.
